(19) United States
(12) Patent Application Publication
(10) Pub. No.: US 2024/0016052 A1
(43) Pub. Date: Jan. 11, 2024

(54) TANDEM PHOTOVOLTAIC DEVICE COMBINING A SILICON-BASED SUB-CELL AND A PEROVSKITE-BASED SUB-CELL INCLUDING AN N-LAYER WITH CONTROLLED CARBON CONTENT

(71) Applicants: COMMISSARIAT À L'ÉNERGIE ATOMIQUE ET AUX ÉNERGIES ALTERNATIVES, Paris (FR); ENEL GREEN POWER ITALIA SRL, Roma (IT)

(72) Inventors: Matthieu Manceau, Grenoble (FR); Stéphane Cros, Grenoble (FR); Pia Dally, Grenoble (FR); Olivier Dupre, Grenoble (FR); Noella Lemaitre, Grenoble (FR)

(21) Appl. No.: 18/251,920

(22) PCT Filed: Oct. 25, 2021
(86) PCT No.: PCT/FR2021/051874

§ 371 Date: May 5, 2023

(30) Foreign Application Priority Data
Nov. 5, 2020 (FR) FR2011348

(51) Int. Cl. H10K 85/50; H10K 30/57; H10K 30/10

(52) U.S. Cl. CPC H10K 85/50; H10K 30/57; H10K 30/10

(57) ABSTRACT

Tandem photovoltaic device combining a silicon-based sub-cell and a perovskite-based sub-cell including an N-layer with a controlled carbon content. A tandem photovoltaic device, comprising, in this superimposition order: A/ a silicon-based sub-cell A, in particular a silicon heterojunction sub-cell or a TOPCon architecture sub-cell; and B/ a perovskite-based sub-cell B, comprising at least: —an N-type conductive or semiconductor layer (ETL); —a P-type conductive or semiconductor layer (HTL); and —a perovskite-type active layer, interposed between said N-type and P-type conductive or semiconductor layers, wherein the N-type conductive or semiconductor layer is based on individualised nanoparticles of N-type metal oxide(s), and has an atomic carbon content lower than or equal to 20%.

### TECHNICAL FIELD

The present invention relates to the field of tandem-type photovoltaic devices, in particular tandem-type photovoltaic cells, combining a silicon-based sub-cell and a perovskite-based sub-cell.

More particularly, it relates to such silicon/perovskite tandem photovoltaic devices, including, at the perovskite-based sub-cell, a N-type layer with a controlled carbon content, allowing reaching improved performances in terms of photovoltaic conversion efficiency.

### PRIOR ART

Photovoltaic devices, and in particular photovoltaic cells, generally comprise a multilayer stack including a photo-active layer, called the “active” layer. In so-called perovskite-type photovoltaic cells, the active layer consists of a halogenated perovskite type material, which may be an organic-inorganic hybrid or purely inorganic. This active layer is in contact on either side with an N-type conductive or semiconductor layer and a P-type conductive or semiconductor layer. This type of multilayer assembly, comprising the superposition of the active layer and of the two P-type and N-type layers described hereinabove is conventionally referred to as “NIP” or “PIN” depending on the stacking order of the different layers over the substrate.

For example, as represented in FIG. 1, a single-junction perovskite-type photovoltaic cell, with a NIP structure, typically includes a multilayer structure comprising, in this stacking order, a transparent substrate (S), a first transparent electrode also called the lower electrode (E₁), such as a layer made of transparent conductive oxide (TCO), an N-type conductive or semiconductor layer, a perovskite (PK) type active layer, a P-type conductive or semiconductor layer and a second electrode, also called the upper electrode (E₂) (which may be made of metal, for example silver or gold).

In order to increase the efficiency of photovoltaic cells, tandem photovoltaic devices have recently been developed. These tandem devices allow widening the absorption range of the electromagnetic spectrum, by association of two cells absorbing photons of different wavelengths.

Tandem devices may consist of a perovskite-based cell and a silicon-based cell. Different structure types have been developed, such as two-terminal (2T) structures and four-terminal (4T) structures, as schematically represented in FIG. 2. In general, the 2T structures include two electrodes, each forming an anode and a cathode common to the two sub-cells, while the 4T structures include four electrodes, each sub-cell having its pair of electrodes.

For example, FIG. 3 represents a tandem device in a 2T structure including a first silicon-based sub-cell, for example with a silicon homojunction (c-Si), surmounted by a perovskite-based sub-cell in a NIP structure and connected to the silicon-based sub-cell through a recombination layer (RC).

In this perovskite-based sub-cell type, the N-type conductive layer generally consists of a N-type semiconductor oxide, for example ZnO, AZO (aluminium-doped zinc oxide), SnO₂ or TiOₓ (x<2). This layer may be in the so-called mesoporous or planar form. In turn, the P-type conductive layer consists, in most cases, of a semiconductor organic material which may be a n-conjugated polymer, like for example poly(3-hexylthiophene) or P3HT, or a small molecule like Spiro-MeOTAD (2,2′,7,7′-Tetrakis[N,N-di(4-methoxyphenyl)amino]-9,9′-spirobifluorene).

At the present time, the best photovoltaic performances are obtained with devices for which a N-type metal oxide based dense conductive layer is obtained upon completion of a heat treatment at high temperature, typically at temperatures strictly higher than 200° C. For example, such heat treatments at high temperature, in particular at a temperature higher than 400° C., are implemented for the preparation of photovoltaic cells where the N layer is formed from a titanium oxide in a mesoporous form. This is also the case for making N-type layers by a sol-gel process, in particular based on tin oxide (SnO₂) generated from a SnCl₂ precursor.

Unfortunately, the implementation of these heat treatments at high temperature cannot be considered for making N layers at the surface of structures that do not withstand these high temperatures, for example for heterojunction silicon cells for 2T tandem type photovoltaic devices.

To overcome this drawback, alternative methods have already been suggested proceeding with the preparation of the N layer at low temperature, typically at temperatures lower than 150° C. For example, an alternative for preparing a N-type conductive layer at low temperature for a photovoltaic cell in a NIP structure, without affecting the photovoltaic efficiency of the cell, consists in adding a fullerene layer, for example of PCBM, between the N-type metal oxide and the overlying active layer made of perovskite, in order to facilitate the extraction of the charges. Nonetheless, such a method is complex to implement, in particular because the thickness of the deposited fullerene layer should be extremely small, typically in the range of a few nanometres.

It has also been suggested, in order to prepare a N-type conductive layer in low-temperature conditions, to carry out depositions via vacuum techniques, for example by a atomic thin layer deposition process ALD (standing for “Atomic Layer Deposition”) or else by electron beam evaporation. Nevertheless, these techniques are still more complex to implement.

Consequently, there is still a need for an easy method for preparing, in low-temperature conditions, a N-type conductive layer in a perovskite-based sub-cell, and allowing reaching high photovoltaic efficiencies of the tandem device, integrating such a perovskite-based sub-cell.

### SUMMARY OF THE INVENTION

The present invention aims specifically to provide a new method for preparing, at low temperature, a N-type conductive oxide based conductive layer in a perovskite-based sub-cell useful for tandem photovoltaic devices, in particular 2T HET/PK type ones, allowing reaching excellent performances, in particular in terms of photovoltaic efficiency.

Unexpectedly, the Inventors have noticed that it was possible to make tandem photovoltaic devices featuring excellent performances, including a perovskite-based sub-cell integrating a N-type metal oxide based layer prepared at low temperature, subject to the control of the atom concentration of carbon in said N layer.

More specifically, according to a first aspect thereof, the present invention relates to a tandem photovoltaic device, comprising, in this superimposition order:

A/ a silicon-based sub-cell A comprising at least:
a substrate made of crystalline, for example monocrystalline or polycrystalline, silicon in particular N-type or P-type doped; and
at least one layer, distinct from said substrate made of crystalline silicon, of amorphous or polycrystalline silicon, N or P doped;
and B/ a perovskite-based sub-cell B, including at least:
a N-type conductive or semiconductor layer, also called “electron transporting layer” (also denoted “ETL” standing for “Electron Transporting Layer”);
a P-type conductive or semiconductor layer, also called “hole transporting layer” (denoted “HTL” standing for “Hole Transporting Layer”); and
a perovskite-type layer that is active from a photovoltaic point of view, called “photo-active layer” or “active layer”, interposed between said N-type and P-type conductive or semiconductor layers,
wherein said N-type conductive or semiconductor layer is based on individualised nanoparticles of N-type metal oxide(s), and has an atomic carbon content lower than or equal to 20%.

The active layer is in contact with the individualised nanoparticles of N-type metal oxide(s) of the N-type conductive or semiconductor layer. In other words, there is no intermediate layer between the nanoparticles and the active layer.

As detailed in the rest of the text, the perovskite-based sub-cell B of the tandem device according to the invention may have a NIP or PIN structure, preferably a NIP structure.

More particularly, a perovskite-based sub-cell B according to the invention may comprise, in this superimposition order, at least:
a conductive or semiconductor layer of the N type (“ETL”) as defined before, in the case of a NIP structure, or a conductive or semiconductor layer of the P type (“HTL”) in the case of a PIN structure;
a perovskite-type active layer;
a conductive or semiconductor layer of the P type (“HTL”) in the case of a NIP structure, or a conductive or semiconductor layer of the N type (“ETL”) as defined before, in the case of a PIN structure; and
an electrode, called upper electrode, E2^{B}.

According to another aspect thereof, the invention relates to a method for manufacturing a tandem photovoltaic device according to the invention, comprising at least the following steps:
making a silicon-based sub-cell A, as defined before; and
(b) making a perovskite-based sub-cell B as defined before, at least via:
a step of forming said N-type conductive or semiconductor layer from a dispersion of N-type metal oxide nanoparticles in a solvent medium, at a temperature lower than or equal to 150° C., and in operating conditions adjusted so as to obtain the desired atomic carbon content in said N layer, lower than or equal to 20%, and
a step during which the active layer is formed over the surface of the N-type metal oxide nanoparticles.

As illustrated in the following examples, the control of the carbon content in the N-type layer, formed in low-temperature conditions, allows accessing devices having excellent photovoltaic performances, in particular in terms of photovoltaic conversion efficiency.

As detailed in the rest of the text, according to a first alternative, the carbon content in the N-type layer formed according to the invention may be adjusted by implementing a dispersion of metal oxide nanoparticles having a reduced carbon precursor level, such that it allows leading to the desired atomic carbon content, lower than or equal to 20%, in the formed N layer. For example, such dispersions of metal oxide nanoparticles consist of dispersions stabilised via the surface potential of the nanoparticles, and consequently having a reduced level of compatibilising agents.

According to another alternative, the carbon content in the N-type layer according to the invention may be adjusted by subjecting, after deposition of said dispersion of metal oxide nanoparticles and prior to the deposition of the overlying layer, the N-type layer to a treatment for eliminating carbon, in particular by UV irradiation, by UV-ozone, with ozone and/or by plasma, in particular oxidising.

Moreover, advantageously, the low-temperature conditions, preferably lower than or equal to 120° C., advantageously lower than or equal to 100° C., in particular lower than or equal to 80° C. and more particularly lower than or equal to 50° C., enable the formation of the N layer in sub-cells with various structures, in particular at the surface of structures sensitive to high temperatures. In particular, the method for preparing a N layer according to the invention t low temperature allows considering formation thereof at the surface of a perovskite-type active layer in the case of a sub-cell B in a PIN structure.

As detailed in the rest of the text, the tandem photovoltaic device according to the invention may for example have a structure with two terminals (2T).

Other features, variants and advantages of the tandem photovoltaic devices according to the invention, and of preparation thereof, will appear better upon reading the following description, examples and figures, given as a non-limiting illustration of the invention.

### BRIEF DESCRIPTION OF THE DRAWINGS

FIG. 1 schematically represents, in a vertical sectional plane, a conventional single-junction photovoltaic cell, with a NIP structure.

FIG. 2 schematically illustrates a tandem photovoltaic device having 2 terminals (2T) or 4 terminals (4T).

FIG. 3 schematically represents, in a vertical sectional plane, a conventional tandem photovoltaic cell, having a silicon-based sub-cell A (“c-Si”) and a perovskite-based sub-cell B with a NIP architecture.

FIG. 4 schematically represents, in a vertical sectional plane, the structure of a HET/perovskite tandem cell in a 2T structure according to the invention, comprising a silicon heterojunction sub-cell A and a perovskite-based sub-cell B integrating a N-type layer (“ETL”) according to the invention.

FIG. 5 schematically represents, in a vertical sectional plane, the structure of a TOPCon/perovskite tandem cell according to the invention, comprising a silicon-based sub-cell A according to a first variant with a TOPCon structure and a perovskite-based sub-cell B integrating a N-type layer (“ETL”) according to the invention.

FIG. 6 schematically represents, in a vertical sectional plane, the structure of a TOPCon/perovskite tandem cell according to the invention, comprising a silicon-based sub-cell A according to a second variant with a TOPCon structure and a perovskite-based sub-cell B integrating a N-type layer (“ETL”) according to the invention.

It should be noted that, for clarity, the different elements in the figures are plotted in free scale, the actual dimensions of the different portions not being complied with.

FIG. 7 shows the evolution of the atomic concentration of carbon in a N layer based on AZO nanoparticles as a function of the duration of the UV-ozone treatment, in the conditions of Example 1.b.

FIG. 8 schematically shows, in a vertical sectional plane, a single-junction photovoltaic cell, with a NIP structure, with illumination from the top, as tested in Example 2.

FIG. 9 is a photograph, in top view, of the PV device tested in Example 2, composed by five strips connected in series.

In the rest of the text, the expressions “comprised between . . . and . . . ”, “ranging from . . . to . . . ” and “varying from . . . to . . . ” are equivalent and are intended to mean that the bounds are included unless stated otherwise.

### DETAILED DESCRIPTION

As indicated before, the invention relates, according to a first aspect thereof, to a tandem photovoltaic device, in particular a tandem photovoltaic cell, comprising, in this superimposition order:

A/ a silicon-based sub-cell A comprising at least:
a substrate made of crystalline, for example monocrystalline or polycrystalline, silicon in particular N-type or P-type doped; and
at least one layer, distinct from said substrate made of crystalline silicon, of amorphous or polycrystalline silicon, N or P doped;
and B/ a perovskite-based sub-cell B, including at least:
a N-type conductive or semiconductor layer, also called “electron transporting layer” (also denoted “ETL” standing for “Electron Transporting Layer”);
a P-type conductive or semiconductor layer, also called “hole transporting layer” (denoted “HTL” standing for “Hole Transporting Layer”); and
a perovskite-type active layer, interposed between said N-type and P-type conductive or semiconductor layers,
wherein said N-type conductive or semiconductor layer is based on individualised nanoparticles of N-type metal oxide(s), and has an atomic carbon content lower than or equal to 20%.

It also relates to a method for manufacturing a tandem photovoltaic device, in particular a tandem photovoltaic cell, comprising at least the following steps:
making a silicon-based sub-cell A, comprising at least:
a substrate made of crystalline, for example monocrystalline or polycrystalline, silicon in particular N-type or P-type doped; and
at least one layer, distinct from said substrate made of crystalline silicon, of amorphous or polycrystalline silicon, N or P doped;
(b) making a perovskite-based sub-cell B, comprising at least:
an N-type conductive or semiconductor layer (“ETL”);
a P-type conductive or semiconductor layer (“HTL”); and
a perovskite-type active layer, interposed between said N-type and P-type conductive or semiconductor layers,
wherein said N-type conductive layer is formed from a dispersion of N-type metal oxide nanoparticles in a solvent medium, at a temperature lower than or equal to 150° C., and in operating conditions adjusted so as to obtain the desired carbon content in said N layer.

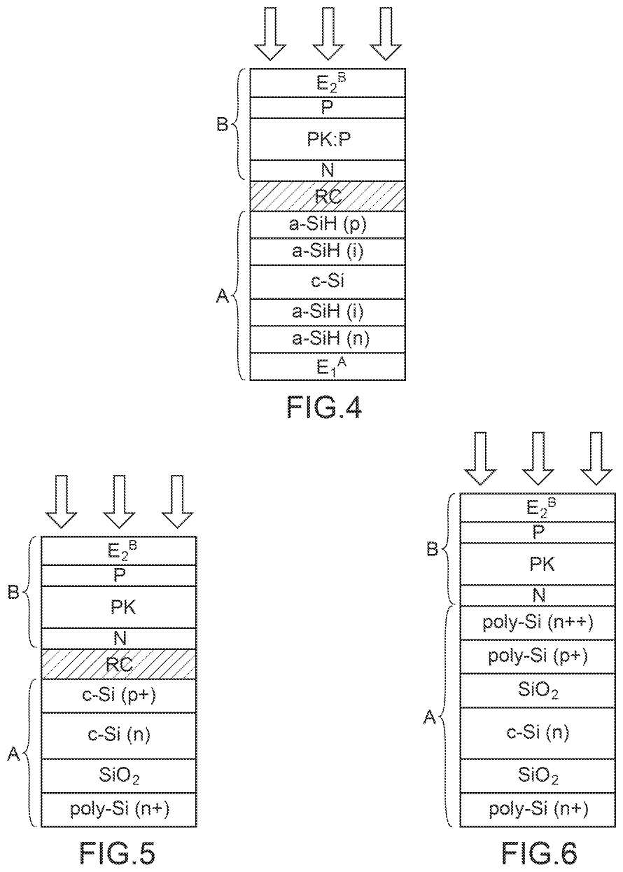

As schematically represented in FIGS. 4 to 6, the illumination of a 2T tandem device according to the invention is done through the upper electrode of the perovskite-based sub-cell B

Unless indicated otherwise, an N-type (respectively P-type) layer according to the invention may consist of one single N-type (respectively P-type) doped layer or of a multilayer stack of at least two sub-layers, for example of three N-type (respectively P-type) doped sub-layers.

Silicon-Based Sub-Cell A:

As stated before, the perovskite-based sub-cell B is stacked over a silicon-based sub-cell A comprising at least one substrate made of crystalline, for example monocrystalline or polycrystalline, silicon possibly N-type or P-type doped; and at least one layer, distinct from said substrate made of crystalline silicon, of amorphous or polycrystalline silicon, N- or P-doped.

Thus, a sub-cell A implemented in a tandem photovoltaic device according to the invention comprises at least two distinct materials, a substrate made of crystalline, in particular monocrystalline, silicon in particular N-type or P-type doped, on the one hand, and a distinct layer made of N- or P-doped amorphous or polycrystalline silicon. Thus, it differs in particular from a silicon homojunction sub-cell

According to a first variant, the tandem photovoltaic device according to the invention may comprise a silicon heterojunction sub-cell A (also called “HET”).

According to another variant, it may consist of a sub-cell A in a “TOPCon” type architecture (standing for “Tunnel-Oxide-Passivated Contact”).

Such structures will be more specifically detailed in the rest of the text.

Silicon heterojunction sub-cell A:

According to a particular embodiment, the photovoltaic device according to the invention includes a silicon heterojunction sub-cell A. Any type of conventional silicon heterojunction cell may be suitable for the photovoltaic device according to the invention.

In particular, a silicon heterojunction sub-cell A comprises a substrate made of crystalline, for example monocrystalline or polycrystalline, silicon in particular N-type or P-type doped and including, on either side of said substrate, two conductive or semiconductor layers made of amorphous silicon, N and P doped, or highly N⁺ and P⁺ doped. Advantageously, an intermediate so-called passivation layer, generally a layer made of intrinsic amorphous silicon, i.e. non-doped, is disposed between the substrate made of silicon and each of the conductive or semiconductor layers.

As represented in FIG. 4, the sub-cell A may more particularly comprise, in this stacking order:
a first electrode denoted E1^{A};
a layer made of N-doped (or P-doped) amorphous silicon;
advantageously, a layer based on intrinsic amorphous silicon, serving as a passivation layer;
a substrate made of crystalline silicon as described before, in particular monocrystalline, in particular N-type doped;
advantageously, a layer based on intrinsic amorphous silicon, serving as a passivation layer;
a layer made of P-doped (or N-doped) amorphous silicon; and
optionally, a second electrode E2^{A}.

The first electrode E1^{A} may be formed of a metallised conductive or semiconductor transparent layer, in particular of transparent conductive oxide(s) (TCO) such as tin-doped indium oxide (ITO), aluminium-doped zinc oxide (AZO), gallium-doped zinc oxide (GZO), indium-doped zinc oxide (IZO) and mixtures thereof, or be formed of a multilayer assembly, for example AZO/Ag/AZO.

It may also be formed of a network of nanowires, in particular made of silver.

For example, the first electrode E1^{A} may consist of a metallised transparent conductive oxide layer, in particular a metallised ITO layer.

It may have a thickness ranging from 40 to 200 nm, in particular from 50 to 100 nm, for example about 70 nm.

The sub-cell A may comprise a second electrode E2^{A} when the tandem device has a 4-terminal (4T) structure.

When present, the second electrode E2^{A} is advantageously formed of a metallised conductive or semiconductor transparent layer, in particular as described for the first electrode E1^{A}. Furthermore, it may have the characteristics mentioned for the first electrode E1^{A}.

The metallisation of the first electrode E1^{A} and, where appropriate, the second electrode E2^{A}, may be carried out by evaporation of a metal (gold or silver). It may also be carried out by screen-printing or by inkjet. In general, it consists in forming a grid.

Advantageously, the layer made of N-doped amorphous silicon is a layer made of hydrogenated amorphous silicon (denoted “a-Si:H(n)”). It may have a thickness comprised between 1 and 30 nm, in particular between 1 and 10 nm.

Advantageously, the layer made of P-doped amorphous silicon is a layer made of hydrogenated amorphous silicon (denoted “a-Si:H(p)”). It may have a thickness comprised between 1 and 30 nm, in particular between 5 and 15 nm.

More particularly, said passivation layer(s) may be made of hydrogenated amorphous silicon ((i) a-Si:H). They may have, independently of each other, a thickness comprised between 1 and 30 nm, in particular between 5 and 15 nm.

Advantageously, the crystalline silicon (“c-Si”) substrate is a silicon monocrystalline substrate, in particular of the N type. In particular, it has a thickness comprised between 50 and 500 nm, in particular between 100 and 300 nm.

The crystalline silicon substrate is positioned between the N-doped amorphous silicon layer (“a-Si:H(n)”) and the P-doped amorphous silicon layer (“a-Si:H(p)”), where appropriate between the two passivation layers (“a-Si:H(i)”).

Preparation of the Silicon Heterojunction Sub-Cell A:

The silicon heterojunction sub-cell A may be made by methods known to a person skilled in the art.

A silicon heterojunction sub-cell A may be made according to the following steps:
texturing the surface and cleaning a substrate made of crystalline silicon, in particular monocrystalline, possibly N-doped;
advantageously, chemical-mechanical polishing (CMP) at least the face of the substrate made of silicon intended to face the perovskite-based sub-cell B, and cleaning after polishing;
advantageously, depositing a layer based on intrinsic amorphous silicon (a-Si:H(i)) serving as a passivation layer over each of the faces of the substrate made of crystalline silicon;
depositing a layer made of N-doped amorphous silicon (a-Si:H(n)) over one of the faces of the substrate made of crystalline silicon, advantageously over the passivation layer;
depositing a layer made of P-doped amorphous silicon (a-Si:H(p)) over the other face of the substrate made of crystalline silicon, advantageously over the passivation layer;
depositing an electronically conductive or semiconductor layer over the layer made of N-doped (or P-doped) amorphous silicon, and metallisation of said electronically conductive or semiconductor layer, so as to form a first electrode E1^{A}, called the lower electrode;
optionally, depositing an electronically conductive or semiconductor layer over the layer made of P-doped (or N-doped) amorphous silicon, and metallisation of said electrically conductive or semiconductor layer, so as to form a second electrode E1^{B}, in the case of a structure with four terminals.

Advantageously, the step of cleaning the substrate made of silicon may be carried out by the so-called “saw damage removal” (SDR) technique. It allows avoiding the costly and time-consuming lapping and polishing process, by proceeding with wet etching in an alkaline solution such as potassium hydroxide (KOH) or sodium hydroxide, in order to eliminate damages caused by the saw (“saw damage”) on the plates after cutting thereof.

Conventionally, texturing is carried out, after cleaning the substrate through at least one anisotropic etching step using an alkaline solution, such as potassium hydroxide (KOH) or sodium hydroxide (NaOH).

The chemical-mechanical polishing (“CMP”) allows obtaining a low surface roughness. Cleaning after polishing allows removing the contamination introduced by polishing, composed of micro- and nano-particles, organic and metallic contamination, without degrading the surface morphology. In general, it is carried out through a wet process. In particular, it may be carried out by successive soaking in a bath under ultrasound of water and isopropyl alcohol at 80° C. and/or UV-Ozone treatment, in particular for a duration ranging from 1 to 60 minutes, in particular about 30 minutes.

The deposition of the different layers made of P-doped or N-doped amorphous silicon may be carried out by plasma-enhanced chemical vapour deposition (PECVD standing for “Plasma Enhanced Chemical Vapour Deposition”), during which a doping gas is introduced in order to dope the layers made of amorphous silicon.

The electronically conductive or semiconductor layer intended to form the first electrode E1A may be deposited by physical vapour deposition (“PVD” standing for “Physical Vapour Deposition”), in particular by sputtering.

The same applies for the formation of the second electrode E1B, when present.

As detailed in the rest of the text, metal contacts are formed afterwards in the context of manufacture of the tandem device over the layer intended to form the first electrode E1A, and possibly, in the context of a 4T structure, over the layer intended to form the second electrode E1B.

Of course, the invention is not limited to the HET sub-cell configuration described before and schematically represented in FIG. 4. Other structures may be considered, for example integrating a passivation layer made of silicon oxide SiOx.

Silicon-Based Sub-Cell A in a TOPCon-Like Structure

According to another particular embodiment, the photovoltaic device according to the invention includes a sub-cell A in a “TOPCon”-type architecture (according to the naming of the Fraunhofer ISE “Tunnel Oxide Passivated Contact”, also called “POLO” standing for “POLy silicon on Oxide” according to the naming of the Institute for Solar Energy Research in Hameln (ISFH)) [2]. Any type of known cell of the TopCon type may be suitable for the photovoltaic device according to the invention.

Several TOPCon-type structure variants may be considered.

As represented in FIGS. 5 and 6, a sub-cell A in a TOPCon-type architecture may comprise at least:
a substrate made of N- or P-doped crystalline silicon (“c-Si(n)” or “c-Si(p)”), in particular N-doped;
at the face of the substrate intended to form the rear face of the tandem photovoltaic device (FAR), a layer made of highly N+ (“poly-Si(n+)”) or P+ (“poly-Si(p+)”) doped polycrystalline silicon, said layer made of highly doped polycrystalline silicon being separated from the substrate by a passivation layer made of an oxide so-called “tunnel oxide”, in particular of silicon oxide SiOx or of aluminium oxide AlOx;
on the side of the opposite face of the substrate, at least one layer made of highly P+ or N+ doped crystalline or polycrystalline silicon of the electrical type opposite to that of the substrate.

It has been demonstrated that the joint use of a layer made of tunnel oxide and a layer made of highly N+ (or P+) doped polycrystalline silicon at the FAR allows having excellent surface passivation as well as an effective transport of charges. Contact is maintained because the passivation layer made of silicon oxide enables the charge carriers (electrons and holes) to pass through by tunnel effect thanks to a quantum phenomenon.

Advantageously, the crystalline silicon substrate is an N-type silicon crystalline substrate (c-Si (n)). In particular, it may have a thickness comprised between 50 and 500 nm, in particular between 100 and 300 nm.

The silicon substrate is covered successively at its face intended to form the rear face of the photovoltaic device, with a passivation layer and with a layer made of highly doped polycrystalline silicon.

The tunnel oxide layer may be a layer made of SiOx or of AlOx, in particular of SiO₂. Advantageously, it has a thickness comprised between 0.5 and 10 nm, in particular between 1 and 5 nm.

According to a particular embodiment, the layer made of highly doped polycrystalline silicon may be an oxygen- or carbon-rich layer.

According to a particular embodiment, the layer made of highly doped polycrystalline silicon is of the N+ type (poly-Si(n+)).

By “highly doped”, it should be understood that the layer has a doping level higher by at least one order of magnitude with respect to the doping level of the substrate. We then talk about N+ or P+ doping in case of high doping instead of N or P in case of doping of the same order of magnitude as that of the substrate. For example, a so-called “highly doped” layer may have a doping with a concentration of electrically-active dopants higher than 10¹⁷ at·cm⁻³, in particular between 10¹⁷ and 10²² at·cm⁻³, preferably between 10¹⁹ and 10²¹ at·cm⁻³.

The layer made of highly doped polycrystalline silicon at the FAR of the device may have a thickness comprised between 5 and 500 nm, in particular between 10 and 250 nm.

According to a first embodiment, as represented in FIG. 5, a sub-cell A in a TOPCon structure, may comprise in this stacking order:
a layer made of highly N⁺ (or P⁺) doped polycrystalline silicon “poly-Si(n+)”;
a layer, called passivation layer, made of silicon oxide, in particular of SiO₂;
a substrate made of N-doped (or P-doped) crystalline silicon “c-Si(n)”;
a layer made of highly doped crystalline silicon of the electrical type opposite to that of the P⁺ (or N⁺) substrate “c-Si(p+)”.

In the rest of the text, a sub-cell A having the aforementioned structure will be referred to as “TOPCon 1” structure.

The layers made of highly doped polycrystalline silicon, the passivation layer made of silicon oxide and the substrate made of crystalline silicon may have the previously-described features.

The layer made of highly doped crystalline silicon of the electrical type opposite to that of the P⁺ (or N⁺) substrate “c-Si(p+)” may have a thickness comprised between 50 nm and 1 μm, in particular between 200 and 700 nm.

As detailed in the rest of the text, a metallisation layer may be formed afterwards on the surface of the layer made of highly doped polycrystalline silicon forming the FAR of the tandem device.

According to another embodiment, as represented in FIG. 6, a sub-cell A in a TOPCon structure may comprise in this stacking order:
a layer made of highly N⁺ (or P⁺) doped polycrystalline silicon “poly-Si(n+)”;
a layer, called passivation layer, made of silicon oxide, in particular of SiO₂;
a substrate made of N-doped (or P-doped) crystalline silicon “c-Si(n)”;
a layer, called passivation layer, made of silicon oxide, in particular of SiO₂;
a layer made of highly doped polycrystalline silicon of the electrical type opposite to that of the P⁺ (or N⁺) substrate “poly-Si(p+)”;
a layer of very highly doped polycrystalline silicon of the electrical type opposite to that of the underlying layer made of N⁺ (or P⁺⁺) polycrystalline silicon “poly-Si(n++)”.

In the rest of the text, a sub-cell A having the aforementioned structure will be referred to as “TOPCon 2” structure.

The layer made of highly doped polycrystalline silicon, the first passivation layer made of silicon oxide and the substrate made of crystalline silicon may have the previously-described features.

The second passivation layer made of silicon oxide may have the characteristics described before for the first passivation layer.

The layer made of highly P⁺ (or N⁺) doped polycrystalline silicon covering the second passivation layer, may have the characteristics, in particular in terms of thickness and doping level, described before for the layer made of highly N⁺ (or P⁺) doped polycrystalline silicon located at the FAR of the device.

The layer made of very highly N⁺⁺ (or P⁺⁺) doped polycrystalline silicon is characterised by a higher doping level compared to the doping level of an N⁺ (or P⁺) doped layer. In particular, a so-called “very highly doped” layer may have a doping with a concentration of dopants higher than 10²⁰ at·cm⁻³, in particular comprised between 10²⁰ and 10²² at·cm⁻³.

The layer made of very highly N⁺⁺ (or P⁺⁺) doped polycrystalline silicon may have a thickness comprised between 5 nm and 60 nm, in particular between 20 nm and 40 nm.

As described in the rest of the text, in the case of this last variant of the TOPCon type A sub-cell, the sub-cell A and the superimposed perovskite-based sub-cell B may be connected for the preparation of the tandem device with two terminals, without implementing a so-called the recombination layer.

Preparation of the TOPCon-Type Sub-Cell A:

A sub-cell with a TOPCon structure, as described before, may be prepared by methods known to a person skilled in the art.

For example, a sub-cell A with a TOPCon 1 structure as described before may for example be made according to the following steps:
texturing the surface and cleaning a substrate made of N-doped (or P-doped) crystalline silicon;
advantageously, polishing at least the face of the substrate made of silicon intended to face the perovskite-based sub-cell B, and cleaning after polishing;
depositing a layer of silicon oxide SiOₓ, in particular SiO₂, serving as a passivation layer at the opposite face of the substrate made of crystalline silicon;
depositing over the passivation layer a layer made of highly N⁺ (or P⁺) doped polycrystalline silicon “poly-Si(n+)”;
depositing over the face of the substrate opposite to that coated with the passivation layer, a layer made of highly doped crystalline silicon, of the electrical type opposite to that of the substrate made of P⁺ (or N⁺) silicon, “c-Si(p+)”.

A sub-cell A with a TOPCon 2 structure as described before may be made according to the following steps:
texturing the surface and cleaning a substrate made of N-doped (or P-doped) crystalline silicon;
advantageously, polishing at least the face of the substrate made of silicon intended to face the perovskite-based sub-cell B, and cleaning after polishing;
depositing a layer of silicon oxide SiOₓ, in particular SiO₂, serving as a passivation layer on either side of the substrate made of crystalline silicon;
depositing a layer made of highly N⁺ doped polycrystalline silicon “poly-Si(n+)” over one of the passivation layers;
depositing a layer made of highly doped polycrystalline silicon, of the electrical type opposite to that of the substrate, P⁺ “poly-Si(p+)” (or N⁺) over the other passivation layer;
depositing, over the surface of the layer made of highly P⁺ (or N⁺) doped polycrystalline silicon, of the electrical type opposite to that of the substrate, a layer made of very highly doped polycrystalline silicon of the electrical type opposite to that of the underlying layer, N⁺⁺ “poly-Si (n++)” (or P⁺⁺).

Advantageously, the preparation steps (texturing, cleaning, chemical-mechanical polishing) may be carried out as described before for the silicon heterojunction sub-cell A.

The passivation layer(s) made of silicon oxide may be formed by thermal or chemical oxidation at the surface of the substrate made of crystalline silicon. The thermal oxidation of the substrate made of crystalline silicon may be carried out in a furnace in the presence of an oxygen-rich atmosphere at moderate temperatures (600-700° C.). The in situ thermal oxidation of the crystalline silicon, directly in the deposition chamber by LPCVD (“Low-Pressure Chemical Vapour Deposition”) used for the subsequent deposition of the silicon layer, has also been described. For example, the chemical oxidation of the crystalline silicon may be carried out in hot nitric acid (HNO₃) or in a solution of deionised water and ozone (DIO₃). More recently, the formation of this passivation layer made of SiOₓ by plasma oxidation has also been reported, for example directly in the plasma chemical vapour deposition chamber (PECVD standing for “Plasma Enhanced Chemical Vapour Deposition”) used for the subsequent deposition of silicon-based layers. Other dry oxidation processes involving an excimer UV or halogen lamp have also been described.

The layers made of highly P⁺ or N⁺ doped or very highly N⁺⁺ or P⁺⁺ doped polycrystalline silicon may be made by chemical vapour deposition (CVD standing for “Chemical Vapour Deposition”), mainly by LPCVD, but also by PECVD. Other methods have also been described, for example by PVD (“Physical Vapour Deposition”) or by CVD activated by hot filament.

Perovskite-Based Sub-Cell B:

As indicated before, a photovoltaic device according to the invention includes a perovskite-based sub-cell B comprising a perovskite-type active layer interposed between a N-type conductive or semiconductor layer and a P-type conductive or semiconductor layer, wherein said N-type layer is based on N-type metal oxide individualised nanoparticles, and has an atomic carbon content lower than or equal to 20%.

More particularly, the sub-cell B may comprise in this stacking order:
optionally a first electrode E1B;
a lower conductive or semiconductor layer of the N type (denoted “ETL”) in the case of a NIP structure or of the P type (denoted “HTL”) in the case of a PIN structure;
a perovskite-type active layer;
an upper conductive or semiconductor layer of the P type (denoted “HTL”) in the case of a NIP structure or of the N type (denoted “ETL”) in the case of a PIN structure;
said N-type layer being based on N-type metal oxide individualised nanoparticles, and having an atomic carbon content lower than or equal to 20%;
a transparent second electrode, called upper electrode, E2B, and more particularly formed by a metallised transparent conductive oxide layer.

N-Type Conductive or Semiconductor Layer:

A N-type (or “ETL” layer) conductive or semiconductor layer of the sub-cell B according to the invention is more simply referred to in the rest of the text as “N layer”. An “N-type” material refers to a material that enables the transport of electrons (e⁻).

More particularly, the N layer of the sub-cell B according to the invention may be formed of N-type metal oxide individualised nanoparticles.

In particular, the N-type metal oxide nanoparticles may be selected from among nanoparticles of zinc oxide ZnO, titanium oxides TiOₓ with x comprised between 1 and 2, tin oxide (SnO₂), doped zinc oxides, for example aluminium-doped zinc oxide (AZO), indium-doped zinc oxide (IZO), gallium-doped zinc oxide (GZO), doped titanium oxides, for example titanium doped with nitrogen, phosphorus, iron, tungsten or manganese and mixtures thereof.

In particular, the N-type conductive or semiconductor layer of the sub-cell B according to the invention may be formed of metal oxide nanoparticles selected from among tin oxide (SnO₂) nanoparticles, doped zinc oxide nanoparticles, in particular aluminium-doped zinc oxide (AZO) and mixtures thereof.

According to a particular embodiment, the N-type conductive or semiconductor layer of the sub-cell B is formed of tin oxide (SnO₂) nanoparticles.

The N-type metal oxide individualised particles of the N-type conductive or semiconductor layer in the sub-cell B according to the invention may have an average particle size comprised between 2 and 100 nm, in particular comprised between 5 and 50 nm, in particular comprised between 5 and 20 nm and more particularly between 8 and 15 nm.

The particle size may be assessed by transmission electron microscopy.

In the case of particles with a spherical or generally spherical shape, the average particle size relates to the diameter of the particle. In the case where the particles have an uneven shape, the particle size relates to the equivalent diameter of the particle. By equivalent diameter, it should be understood the diameter of a spherical particle that has the same physical property when determining the size of the particle as the measured particle with an uneven shape.

In particular, the N-type metal oxide particles may have a spherical shape. By “spherical particle”, it should be understood particles having the shape or substantially the shape of a sphere.

In particular, spherical particles have a sphericity coefficient higher than or equal to 0.75, in particular higher than or equal to 0.8, in particular higher than or equal to 0.9 and more particularly higher than or equal to 0.95.

The sphericity coefficient of a particle is the ratio of the smallest diameter of the particle to the largest diameter thereof. For a perfect sphere, this ratio is equal to 1.

By “individualised” nanoparticles, it should be understood that the particles keep their state of individual particles within the N layer of the multilayer stack according to the invention, in particular they do not merge together.

In particular, less than 10% of the N-type metal oxide nanoparticles in said N layer are merged, preferably less than 5%, and possibly less than 1%.

For example, this could be clearly viewed by observing the N layer by electron microscopy.

In particular, the N layer based on individualised N-type metal oxide nanoparticle(s) differs from sintered layers, in which the particles are merged together. Thus, the N layer according to the invention is a non-sintered layer.

Structuring of the N-type layer in a sub-cell B according to the invention demonstrates in particular that its preparation, as detailed in the rest of the text, does not involve any step of heat treatment at high temperature, typically at a temperature strictly higher than 150° C., in particular higher than 200° C.

The presence of individualised N-type metal oxide particles, in other words not merged together, at the N-type layer of the sub-cell B according to the invention may also be reflected by a surface roughness of said N-type layer, measured before forming the overlying layer, higher than that obtained for example for a sintered layer.

In particular, a N layer of the sub-cell B according to the invention may have a roughness average value RMS larger than or equal to 3 nm, in particular comprised between 5 and 10 nm.

The surface roughness may be measured by mechanical profilometry.

Moreover, the N-type conductive or semiconductor layer of the sub-cell B according to the invention is characterised by a low carbon content (atomic carbon content), in particular lower than or equal to 20%.

Preferably, a N layer of the sub-cell B according to the invention has an atomic carbon content lower than or equal to 17%, preferably lower than or equal to 15%, in particular comprised between 0 and 15%. The carbon content of a N layer according to the invention may be determined by X-ray photoelectron spectroscopy (XPS standing for “X-Ray photoelectron spectroscopy”).

An N-type conductive or semiconductor layer (“ETL”) of the sub-cell B according to the invention may have a thickness comprised between 5 and 500 nm, in particular between 10 and 80 nm, and more particularly between 30 and 50 nm.

The thickness may be measured with a profilometer, for example from the brand KLA Tencor or with an atomic force microscope, for example from the brand VEECO/INNOVA.

Perovskite-Type Active Layer:

This active layer is formed of a perovskite material. Advantageously, the perovskite material is a material including 1, 2 or 3 cations and anions, for example halides, in particular Cl⁻, Br⁻, I⁻ and mixtures thereof.

More particularly, the perovskite material of the active layer of the sub-cell B according to the invention may be a material of general formula ABX₃, with:
A representing a cation or a combination of metallic or organic cations;
B representing one or more metallic element(s), such as lead (Pb), tin (Sn), bismuth (Bi) and antimony (Sb); and
X representing one or more anion(s), in particular one or more halide(s), and more particularly selected from among chloride, bromide, iodide and mixtures thereof.

In particular, such perovskite materials are described in the document WO 2015/080990.

As examples of perovskite materials, mention may in particular be made of organic-inorganic hybrid perovskites. More particularly, these hybrid perovskite materials may be of the aforementioned ABX3 formula, wherein A comprises one or more organic or non-organic cation(s).

The organic cation may be selected from among organo-ammonium cations such as:
the alkyl-ammonium cations of general formula R₁R₂R₃R₄N+, with R₁, R₂, R₃ and R₄ being independently of each other a hydrogen atom or a C1-C5 alkyl radical, such as a methyl-ammonium (MA+) type cation and
the formamidinium cations (FA+) of formula [R₁NCHNR₁]+, with R₁ possibly representing a hydrogen atom or a C1-C5 alkyl radical.

The organic cation(s) of the hybrid perovskite material may possibly be combined with one or more metallic cation(s), for example caesium.

As examples of hybrid perovskite materials, mention may more particularly be made of the perovskites of formula ABX3, with:
A representing an organo-ammonium cation, for example of the methyl-ammonium (MA+) type, a formamidinium cation (FA+) or a mixture of these two cations, possibly associated with caesium (Cs+);
B being selected from among lead, tin, bismuth, antimony and mixtures thereof; and
X being selected from among chloride, bromide, iodide and mixtures thereof.

In particular, the perovskite material may be CHaNH₃PbI₃, also called MAPI, with lead being replaceable by tin or germanium and iodine being replaceable by chlorine or bromine.

The perovskite material may also be a compound of formula CsₓFA₁₋ₓPb(I_{1-y}Br_{y})₃ with x<0.17; 0<y<1 and FA symbolising the formamidinium cation.

The perovskite-type active layer of the sub-cell B according to the invention may have a thickness comprised between 50 and 2,000 nm, in particular between 200 and 400 nm.

P-Type Conductive or Semiconductor Layer:

A “P-type” material refers to a material enabling the transport of holes (h+).

For example, the P-type material may be selected from among Nafion, WO₃, MoO₃, V₂O₅ and NiO, n-conjugated conductive or semiconductor polymers, possibly doped, and mixtures thereof. Preferably, the P-type material is selected from among n-conjugated conductive or semiconductor polymers, possibly doped.

As an illustration of π-conjugated semiconductor polymers, possibly doped, mention may in particular be made of poly(3,4-ethylenedioxythiophene) (PEDOT), preferably in a form combined with a counteranion such as PEDOT:PSS; poly(3-hexylthiophene) or P3HT, poly[N-9′-heptadecanyl-2,7-carbazole-alt-5,5-(4,7-di-2-thienyl-2′,1′,3′-benzothiadiazole or PCDTBT, poly[2,1,3-benzothiadiazole-4,7-diyl[4,4-bis(2-ethylhexyl)-4H-cyclopenta[2,1-b:3,4-b′]dithiophene-2,6-diyl]] or PCPDTBT, poly(benzo[1,2-b:4,5-b′]dithiophene-alt-thieno[3,4-c]pyrrole-4,6-dione) or PBDTTPD, poly[[4,8-bis[(2-ethylhexyl)oxy] benzo [1,2-b:4,5-b′]dithiophene-2,6-diyl][3-fluoro-2-[(2-ethylhexyl) carbonyl]thieno[3,4-b]thiophenediyl]] or PTB7, poly[bis(4-phenyl)(2,4,6-trimethylphenyl)amine] or PTAA.

A preferred P-type material is a mixture of PEDOT and PSS, or PTAA, possibly doped with a lithium salt, such as lithium bis(trifluoromethane)sulphonide (LiTFSI) and/or 4-tert-butylpyridine (t-BP).

The P-type material may also be selected from among P-type semiconductor molecules such as:
porphyrin;
the: 7,7′-(4,4-bis(2-ethylhexyl)-4H-silolo[3,2-b:4,5-b 2]dithiophene-2,6-diyl)bis(6-fluoro-4-(5′-hexyl-[2,2′-bithiophen]-5-yl)benzo[c][1,2,5]thiadiazole): p-DTS(FBTTh2)2;
boron-dipyromethenes (BODIPY);
molecules with a triphenylamine (TPA) core.

A P-type conductive or semiconductor layer (“HTL”) of the sub-cell B according to the invention may have a thickness comprised between 5 and 500 nm, in particular between 10 and 150 nm.

Alternatively, a P-type layer may be in the form of a self-assembled monolayer (or “SAM” standing for “Self-Assembled Monolayer”), and have a thickness in the range of one nanometer. For example, the document by Al-Ashouri et al. [3] discloses the preparation de SAM from carbazole-based molecules, such as the (2-{3,6-bis[bis(4-methoxyphenyl)amino]-9H-carbazol-9-yl}ethyl)phosphonic acid (V1036), the [2-(3,6-dimethoxy-9H-carbazol-9-yl)ethyl]phosphonic acid (MeO-2PACz) and the [2-(9H-carbazol-9-yl)ethyl]phosphonic acid (2PACz).

Preferably, sub-cell B of a tandem photovoltaic device according to the invention has a so-called NIP structure. The sub-cell B may then comprise, as schematically represented in FIGS. 4 to 6, in this superimposition order:
optionally a first electrode E1B;
an N-type lower conductive or semiconductor layer (denoted “ETL”) as defined before,
a perovskite-type active layer as described before;
a P-type upper conductive or semiconductor layer (denoted “HTL”), in particular as described before, and
a transparent second electrode, called the upper electrode, E2^{B}, in particular formed of a metallised layer made of transparent conductive oxide (TCO).

Alternatively, in the case of a PIN structure, the sub-cell B may comprise in this superimposition order:
optionally a first electrode E1^{B};
a P-type lower conductive or semiconductor layer (denoted “HTL”), in particular as defined before,
a perovskite-type active layer, in particular as described before;
an N-type upper conductive or semiconductor layer (denoted “ETL”) as described before, and
a transparent upper electrode, E2B, in particular formed of a metallised layer made of transparent conductive oxide (TCO).

The upper electrode E2^{B} may be made of a conductive or semiconductor material, and metallised. Advantageously, it is made of a material selected from the group of transparent conductive oxides (TCO), for example ITO (indium-tin oxide), AZO (aluminium-zinc oxide), IZO (indium-zinc oxide) or IOH (hydrogenated indium oxide).

According to a particular embodiment, it consists of an upper electrode made of ITO and metallised.

The upper electrode E2^{B}, in particular made of ITO, may have a thickness comprised between 50 and 300 nm, in particular between 100 and 250 nm and more particularly about 200 nm.

When present as is the case in particular for tandem devices with a 4T structure, the first electrode E1^{B} may be made of a transparent conductive or semiconductor material, and metallised. These may consist of the materials mentioned for the upper electrode E2^{B}. Furthermore, it may have the characteristics, in particular in terms of thickness, mentioned for the electrode E2^{B}.

Preparation of the Perovskite-Based Sub-Cell B:

As indicated before, the perovskite-based sub-cell B according to the invention is prepared by proceeding with forming the N-type conductive or semiconductor layer from a dispersion of N-type metal oxide nanoparticles in a solvent medium, at a temperature lower than or equal to 150° C., and in operating conditions adjusted so as to obtain the desired carbon content in said N layer.

More particularly, making of a sub-cell B according to the invention implements at least the following successive steps:
forming a lower conductive or semiconductor layer of the N type (denoted “ETL”) in the case of a NIP structure or of the P type (denoted “HTL”) in the case of a PIN structure;
forming, on the surface of said lower conductive or semiconductor layer, said perovskite-type active layer:
forming, on the surface o said pervoskite-type active layer, an upper conductive or semiconductor layer of the P type (“HTL”) in the case of a NIP structure or of the N type (“ETL”) in the case of a PIN structure;
depositing an electronically-conductive layer over the upper conductive or semiconductor layer so as to form a transparent electrode E2B, called the upper electrode, in particular made of TCO.

Formation of the N-Type Conductive or Semiconductor Layer:

Advantageously, said N-type conductive or semiconductor layer of the perovskite-based sub-cell B may be formed in conditions of temperature lower than or equal to 120° C., in particular lower than or equal to 100° C., in particular lower than or equal to 80° C., preferably lower than or equal to 50° C., and more particularly at room temperature.

It should be understood that, depending on the NIP or PIN structure of the sub-cell B according to the invention, and the nature of the considered tandem device, for example of the HET/perovskite or TOPCon/perovskite type as detailed in the rest of the text, the nature of the underlying layer, at the surface of which the N-type layer according to the invention is formed, varies.

In the case of a sub-cell B in a NIP structure, the N-type layer may thus be formed at the surface of the recombination layer (RC) intended to connect in series the sub-cells A and B in the case of a 2T structure, at the surface of the upper electrode E2^{A} of the sub-cell A in the case of a 4T structure or at the surface of the upper layer of the sub-cell A if no recombination layer is implemented (for example, at the surface of a layer made of very highly doped polycrystalline silicon, for example “poly-Si (n++)” in the case of a TOPCon 2 type structure as described before). In the case of a sub-cell B in a PIN structure, the N-type layer may be formed at the surface of the perovskite-type active layer.

In the case of forming a N-type layer according to the invention for the preparation of a sub-cell B with a NIP structure, the method according to the invention may comprise more particularly the steps consisting in:
(i) providing a silicon-based sub-cell A, as described before, possibly coated, at the surface of the upper layer made of silicon of the sub-cell A, with a recombination layer (RC) in the case of a 2T structure or an upper electrode E2^{A} in the case of a 4T structure;
(ii) forming, at the surface of said sub-cell A, a N-type (ETL) conductive or semiconductor layer, at a temperature lower than or equal to 150° C., preferably lower than or equal to 100° C. and more preferably lower than or equal to 80° C., from a dispersion of N-type metal oxide nanoparticles in a solvent medium, in operating conditions adjusted so as to obtain an atomic carbon content in the N layer lower than or equal to 20%; and
(iii) successively forming, at the surface of said N-type conductive layer formed upon completion of step (ii), in this superimposition order: a perovskite-type (PK) active layer, a P-type (HTL) conductive or semiconductor layer and a second electrode E2B, called upper electrode, in particular as defined before.

More particularly, the formation of said N-type layer by a solvent process according to the invention implements the deposition of said dispersion of metal oxide nanoparticles, followed by the elimination of said solvent(s).

The deposition of the dispersion may be carried out by means of any technique known to a person skilled in the art, for example selected from among spin-coating or centrifugal coating (“spin-coating”), scraper deposition, blade-coating (“blade-coating”), deposition by ultrasonic spray, slot-die coating (“slot-die”), inkjet printing, rotogravure, flexography and screen-printing.

The solvent medium of said dispersion of metal oxide nanoparticles may comprise one or more solvent(s) selected from among polar solvents such as water and/or alcohols, or ethers (for example alkyl ethers and glycol ethers) or esters (acetate, benzoate or lactones for example). For example, it may consist of water and/or an alcohol, such as butanol.

Of course, the nature of the solvent(s) is selected with regards to the nature of the underlying layer at the surface of which said N-type conductive or semiconductor layer is formed.

It should be understood that the elimination of said solvent(s) is carried out in temperature conditions lower than or equal to 150° C., in particular lower than or equal to 120° C., preferably lower than or equal to 100° C. and more preferably lower than or equal to 80° C. For example, drying of the N layer may be carried out at room temperature. By “room temperature”, it should be understood a temperature of 20° C.±5° C.

According to a first variant, the carbon content in the N-type conductive layer (“ETL”) is controlled by adjusting the level of carbon precursor compounds of the implemented dispersion of metal oxide nanoparticles.

In other words, the N-type layer according to the invention may be formed by deposition of a dispersion of metal oxide nanoparticles having a level of carbon precursor compounds such as the resulting N layer has the desired residual atomic carbon content, lower than 20%.

In particular, the dispersions of metal oxide nanoparticles having a reduced level of carbon precursors compounds consist of dispersions having a low level of compatibilising agents. More particularly, such dispersions comprise less than 5% by weight, in particular less than 1% by weight, of compatibilising agent(s), with respect to the total weigh of the dispersion.

In particular, such dispersions consist of dispersions of nanoparticles stabilised via the surface potential (zeta potential) of the nanoparticles, more specifically by the implementation of counter-ions.

For example, such colloidal dispersions of metal oxide nanoparticles may be available on the market.

According to another variant, the carbon content in the formed N layer (“ETL”) may be adjusted, after deposition of the dispersion of metal oxide nanoparticles and prior to the deposition of the overlying layer in the sub-cell B, for example prior to the deposition of the perovskite (PK) active layer in the case of a sub-cell B in a NIP structure, by subjecting the N-type layer to a carbon elimination treatment.

It should be understood that the carbon elimination treatment is carried out in low-temperature conditions, in particular at a temperature lower than or equal to 150° C., in particular lower than or equal to 120° C., in particular lower than or equal to 100° C., preferably lower than or equal to 80° C. and more particularly lower than or equal to 50° C. For example, the carbon elimination treatment is carried out at room temperature.

More particularly, such a carbon elimination treatment may be a UV irradiation treatment, by UV-ozone, with ozone and/or by plasma, in particular oxidising.

In the context of implementation of such a carbon elimination treatment, it is possible to obtain said N-type conductive or semiconductor layer, having the desired atomic carbon content lower than 20%, starting from any dispersion of metal oxide nanoparticles, regardless of the carbon content of said dispersion.

Of course, in a particular embodiment for preparing a sub-cell B of a device according to the invention, it is possible to combine the aforementioned two variants to reach the desired carbon content in the formed N-type conductive or semiconductor layer.

A person skilled in the art is capable of adjusting the operating conditions of implementation of the carbon elimination treatment, in particular the duration of exposure of the free surface of said N layer to UVs, UV-ozone, to ozone or to a plasma, in particular oxidising, to reach the desired reduced carbon content according to the invention.

More particularly, the treatment under a UV radiation may consist in irradiating the free surface of said N layer formed by a UV light with two wavelengths, for example 185 and 256 nm.

Any UV light source allowing irradiating the surface of said N layer may be used for such an irradiation. For example, mention may be made of a mercury-vapour lamp.

The treatment of said layer by UV irradiation may be carried out for a duration ranging from 5 to 60 minutes, in particular from 10 to 30 minutes.

As indicated before, it is carried out under low-temperature conditions. Preferably, the UV irradiation is carried out at a temperature lower than or equal to 150° C., in particular lower than or equal to 100° C., preferably lower than or equal to 80° C., and pore particularly lower than or equal to 50° C. More particularly, the UV irradiation is carried out at room temperature.

The treatment by UV irradiation may be performed under vacuum or under gas.

In particular, the treatment by UV irradiation may be carried out under ambient atmosphere, the UV radiation then transforming oxygen from the air into ozone; in this case, this is referred to as UV-ozone treatment.

The treatment by UV irradiation may also be carried out under an inert gas such as nitrogen.

According to another particular embodiment, the carbon elimination treatment may consist of a treatment by ozone (in the absence of any UV irradiation).

For example, such a treatment by ozone may be carried out by bringing the free surface of the N layer in contact with an atmosphere containing the ozone generated by the UV irradiation, the sample being placed behind a filter protecting it from said radiation.

According to still another variant, the elimination of carbon may be carried out by plasma treatment, in particular with an oxidising plasma.

For example, the oxidising plasma is a plasma comprising oxygen or a plasma of a mixture of oxygen and argon. Preferably, the treatment is carried out with an oxygen plasma. A person skilled in the art is capable of implementing the equipment necessary for generating such a plasma.

The other layers of the perovskite-based sub-cell B may be made by techniques known to a person skilled in the art. Advantageously, they are made by a wet process, by conventional deposition techniques, i.e. by techniques implementing the deposition of an ink in the liquid state.

In particular, the deposition of a solution during the manufacturing method, in particular to form a P-type conductive or semiconductor layer (“HTL”) and a perovskite-type (“PK”) active layer, may be carried out by means of a technique as described before for the preparation of a N-type conductive or semiconductor layer.

Other deposition techniques may be considered, such as an atomic layer deposition technique (“Atomic Layer Deposition” or “ALD”).

Advantageously, all of the layers formed during the steps of the method may be performed using a unique technique selected from among those described hereinabove.

Advantageously, the preparation of the perovskite active layer implements the so-called “solvent quenching” method, as described in the publication by Xiao et al. ([1]). More particularly, it consists in dripping precursors of the perovskite active layer over the wet film, during spin-coating, an amount of anti-solvent, for example toluene and chlorobenzene, to induce rapid crystallisation of the perovskite. The addition of an anti-solvent, by rapidly reducing the solubility of the perovskite precursors in the solvent medium, advantageously allows promoting nucleation and rapid growth of the perovskite crystals. It has been demonstrated that such a “quenching” operation advantageously allows improving the crystallinity of the perovskite material, upon completion of the thermal annealing, and thus the quality of the resulting perovskite active layer.

Other techniques may also be implemented to form the perovskite active layer and crystallise the perovskite, for example using an air blade (“gas quenching”) in the case of a “slot-die” coating, by a flash vacuum method (“vacuum flash-assisted solution process” or VASP), by a flash infrared annealing method (called “flash infrared annealing” or FIRA), etc.

The electronically-conductive layer intended to form the upper electrode E2B may be deposited by physical vapour deposition (“PVD” standing for “Physical Vapour Deposition”), in particular by sputtering.

Advantageously, the formation of the upper electrode E2B is carried out without preheating to limit as much as possible the degradation of the perovskite-type active layer.

Tandem Photovoltaic Device:

A tandem photovoltaic device according to the invention comprises a sub-cell A as described before, based on silicon, in particular selected from among silicon heterojunction sub-cells and sub-cells in a TOPCon-type architecture, over which is stacked a perovskite-based sub-cell B as described before, comprising in particular a N-type conductive or semiconductor layer as described before, having a controlled atomic carbon concentration.

The invention also relates to a method for manufacturing a tandem photovoltaic device according to the invention, in particular a tandem photovoltaic cell according to the invention, comprising at least the following steps:
making a silicon-based sub-cell A according to the invention, as defined before, in particular with silicon heterojunction or in a TOPCon-type architecture as described before;
(b) making a perovskite-based sub-cell B as defined before, wherein said N-type conductive or semiconductor layer is formed from a dispersion of N-type metal oxide nanoparticles in a solvent medium, at a temperature lower than or equal to 150° C., and in operating conditions adjusted so as to obtain the desired carbon content in said N layer.

The invention will be described more particularly in the rest of the text with reference to a structure with two terminals (2T), wherein the sub-cells A and B are placed in series. Of course, the invention is not limited to 2T tandem devices and other structures may be considered, for example a structure with four terminals (4T).

As described more specifically in the rest of the text, the method for manufacturing a tandem photovoltaic device according to the invention, with a 2T structure, may more particularly comprise forming on the surface of the silicon-based sub-cell A and prior to making of said perovskite-based sub-cell B, an electronically conductive layer, also called the recombination layer.

HET/PK Tandem Device:

According to a first variant, the tandem photovoltaic device according to the invention comprises a silicon heterojunction sub-cell A and a perovskite-based sub-cell B. Such a tandem device is more simply referred to as the “HET/PK tandem device”.

In the case of a 2T HET/PK tandem device, the sub-cells A and B are then placed in series. Thus, the tandem photovoltaic device comprises one single first electrode, the lower electrode E1^{A} of the sub-cell A and one single second electrode, the upper electrode of the sub-cell B E2B.

In this case, the sub-cells A and B are separated by an electronically conductive layer, also called the recombination layer (denoted RC).

Thus, in a HET/PK tandem device in a 2T structure, the upper amorphous silicon-based layer of the P-doped (a-SiH(p)) (or N-doped) (a-SiH(n)) sub-cell A and the lower conductive or semiconductor layer of the sub-cell B, of the N type (ETL) in the case of a NIP structure or of the P type (HTL) in the case of a PIN structure, are separated by a recombination layer (RC).

The recombination layer may have a small thickness, typically comprised between 1 and 20 nm, in particular between 1 and 15 nm and more particularly about 12 nm.

The recombination layer is intended to electrically contact the P-doped or N-doped amorphous silicon layer of the lower sub-cell A and the N-type or P-type conductive or semiconductor layer of the upper sub-cell B, without the charges having to cross a PN junction opposing their transport.

Advantageously, the recombination layer of a tandem device in a 2T structure according to the invention is transparent to the electromagnetic radiation. In particular, it may be made of a material selected from the group of TCOs (transparent conductive oxides) including ITO (Indium Tin Oxide), AZO (Aluminium Zinc Oxide), IZO (Indium Zinc Oxide), IOH (Hydrogenated Indium Oxide), AZO/Ag/IZO, IZO/Ag/IZO, ITOH, IWO, IWOH (indium-tungsten oxide with or without hydrogen), ICO, ICOH (indium-caesium oxide with or without hydrogen), and silver nanowires. It may also consist of GZO (gallium-doped zinc oxide).

According to a particular embodiment, the intermediate layer is made of ITO.

The recombination layer of a HET/PK tandem device according to the invention, in particular the ITO recombination layer, may have a thickness comprised between 1 and 20 nm, in particular between 1 and 15 nm, for example about 12 nm.

Advantageously, the recombination layer comprises as little oxygen as possible to maximise the concentration of carriers to promote recombinations.

Thus, a tandem photovoltaic device in a 2T structure according to the invention may more particularly comprise, in this superimposition order, at least:
a sub-cell A as described before, comprising in this superimposition order:
   A first electrode denoted E1^{A}, in particular formed of a metallised conductive transparent layer;
   a layer made of N-doped (or P-doped) amorphous silicon, preferably of N-doped hydrogenated amorphous silicon “a-SiH (n)” (or P-doped “a-SiH (p)”);
   advantageously, a layer based on intrinsic amorphous silicon, preferably hydrogenated “a-SiH(i)” serving as a passivation layer;
   a substrate made of crystalline silicon, in particular monocrystalline (“c-Si”), and in particular N-doped;
   advantageously, a layer based on intrinsic amorphous silicon, preferably hydrogenated “a-SiH(i)” serving as a passivation layer;
   a layer made of P-doped (or N-doped) amorphous silicon, preferably of P-doped hydrogenated amorphous silicon “a-SiH (p)” (or N-doped “a-SiH (n)”);
an electronically conductive or semiconductor intermediate layer, called “recombination layer”;
a sub-cell B as described before comprising in this superimposition order:
   a lower conductive or semiconductor layer of the N type (denoted “ETL”) in the case of a NIP structure or of the P type (denoted “HTL”) in the case of a PIN structure;
   a perovskite-type active layer;
   an upper conductive or semiconductor layer of the P type (denoted “HTL”) in the case of a NIP structure or of the N type (denoted “ETL”) in the case of a PIN structure;
said N-type layer being based on individualised nanoparticles of N-type metal oxide(s), and having an atomic carbon content lower than or equal to 20%;
   a second electrode, called the upper electrode E2B, in particular formed of a metallised transparent conductive oxide layer.

According to a particular embodiment, as illustrated in FIG. 4, a tandem photovoltaic device in a 2T structure according to the invention comprises the E1^{A}/a_SiH (n)/a-SiH (i)/c-Si/a-SiH (i)/a-SiH (p)/RC/ETL/PK/HTL/E2^{B} stack.

It should be understood that the layers of this stack may have the characteristics described before for each of these layers.

The first electrode E1^{A} and the second electrode E2^{B} may be associated with a metal grid in order to promote external electrical contacts. In particular, this grid may be made of silver or copper.

The invention also relates to a method for manufacturing a HET/perovskite tandem photovoltaic device with two terminals, in particular as described before, comprising at least the following steps:
1/ making a silicon heterojunction sub-cell A containing:
   a first electrode denoted E1^{A}, in particular metallised;
   a layer made of N-doped (or P-doped) amorphous silicon, preferably of N-doped hydrogenated amorphous silicon “a-SiH (n)” (or P-doped “a-SiH (p)”);
   advantageously, a layer based on intrinsic amorphous silicon, preferably hydrogenated “a-SiH(i)” serving as a passivation layer;
   a substrate made of crystalline silicon, in particular monocrystalline (“c-Si”), and in particular N-doped;
   advantageously, a layer based on intrinsic amorphous silicon, preferably hydrogenated “a-SiH(i)” serving as a passivation layer;
   a layer made of P-doped (or N-doped) amorphous silicon, preferably of P-doped hydrogenated amorphous silicon “a-SiH (p)” (or N-doped “a-SiH (n)”);
2/ forming, on the upper amorphous silicon layer of the P-doped (or N-doped) sub-cell A, an electronically conductive or semiconductor intermediate layer (denoted “RC”), called the recombination layer;
3/ making a perovskite-based sub-cell B according to the following steps:
forming, on said recombination layer RC, a N-type “ETL” (or P-type “HTL”) conductive or semiconductor layer, called the lower layer;
forming, on the surface of said lower conductive or semiconductor layer, said perovskite-type active layer;
forming, on the surface of said perovskite-type active layer, a P-type “HTL” (or N-type “ETL”) upper conductive or semiconductor layer.
said N-type conductive layer being formed from a dispersion of N-type metal oxide nanoparticles in a solvent medium, at a temperature lower than or equal to 150° C., and in operating conditions adjusted so as to obtain an atomic carbon content in said N layer, lower than or equal to 20%;
forming, on said upper conductive or semiconductor layer, a second electrode, called the upper electrode, E2B, in particular metallised.

A person skilled in the art is able to adapt the order of the different steps for manufacturing a two-terminal tandem cell.

More particularly, the silicon heterojunction sub-cell A may be prepared according to the previously-described steps.

Advantageously, the PVD deposition of the thin recombination layer, in particular made of ITO, is carried out before that of the electrically conductive layer, which is thicker, in particular made of ITO.

Advantageously, the recombination layer is subjected at its face intended to support the N-type or of P-type conductive or semiconductor layer of the upper perovskite-based sub-cell B, to a prior UV-Ozone treatment, in particular for a duration ranging from 1 to 60 minutes, in particular about 30 minutes.

The perovskite-based sub-cell B may be formed according to the previously-described steps.

Advantageously, the face of the PK:P or PK:N composite layer formed according to the invention is covered, prior to the formation of the upper electrode E2B, with a thin metallic layer (gold or silver) in particular 0.1 to 1 nm thick, so as to improve the transport at the interface of the composite layer and the upper electrode.

The metallisation of the electrode E1^{A} (intended to form the rear face “FAR” of the tandem device) and of the upper electrode E2^{B} (intended to form the front face “FAV” of the tandem device), may be carried out by silver evaporation. It may also be carried out by screen-printing or by inkjet. In general, it consists in forming a grid.

In the case of making by screen-printing, this step is carried out only at the end of the manufacture of the tandem device, simultaneously for the metallisation of the front face and the rear face of the device. The metallisations at the front face and at the rear face are deposited and annealed together.

TopCon/PK Tandem Device:

According to another variant, the tandem photovoltaic device according to the invention comprises a sub-cell A with a TOPCon-type structure and a perovskite-based sub-cell B. Such a tandem device is more simply referred to as a “TOPCon/PK tandem device”.

For example, the sub-cell A may have one of the two architectures “TOPCon 1” and “TOPCon 2” detailed before.

For example, a PK/TOPCon 1 tandem photovoltaic device in a 2T structure according to the invention may comprise, in this superimposition order, at least:
a sub-cell A as described before, comprising in this superimposition order:
   a metallisation layer;
   a layer made of highly N⁺ (or P⁺) doped polycrystalline silicon “poly-Si(n+)”;
   a so-called passivation layer, for example made of silicon oxide, in particular of SiO₂;
   a substrate made of N-doped (or P-doped) crystalline silicon “c-Si(n)”;
   a layer made of highly doped crystalline silicon of the electrical type opposite to that of the P⁺ (or N⁺) substrate “c-Si(p+)”;
an electronically conductive or semiconductor intermediate layer, called “recombination layer”;
a sub-cell B as described before comprising in this superimposition order:
   a lower conductive or semiconductor layer of the N type (denoted “ETL”) in the case of a NIP structure or of the P type (denoted “HTL”) in the case of a PIN structure;
   a perovskite-type active layer;
   an upper conductive or semiconductor layer of the P type (denoted “HTL”) in the case of a NIP structure or of the N type (denoted “ETL”) in the case of a PIN structure;
said N-type layer being based on individualised nanoparticles of N-type metal oxide(s), and having an atomic carbon content lower than or equal to 20%;
   a second electrode, called the upper electrode E2B, in particular metallised.

According to one embodiment, as illustrated in FIG. 5, a TOPCon/PK tandem photovoltaic device in a 2T structure according to the invention comprises the poly-Si (n+)/SiO₂/c-Si (n)/c-Si (p+)/RC/ETL/PK/HTL/E2^{B} stack, the metallisations not being represented.

It should be understood that the layers of this stack may have the characteristics described before for each of these layers.

Advantageously, the recombination layer is made of transparent conductive oxide(s) (TCO), in particular as described before for the recombination layer of a HET/PK tandem device in a 2T structure.

For example, it may be made of indium-tin oxide (ITO), aluminium-doped zinc oxide (AZO), gallium-doped zinc oxide (GZO), indium-doped zinc oxide (IZO) and mixtures thereof, or be formed of a multilayer assembly, for example AZO/Ag/AZO.

The upper electrode E2B may be associated with a metal grid as described in the context of the HET/perovskite devices.

According to another embodiment, a TOPCon/PK photovoltaic device in a 2T structure may comprise a sub-cell A in a TOPCon 2 type architecture as described before and a perovskite-based sub-cell B as described before.

For example, a TOPCon/PK photovoltaic device in a 2T structure according to the invention may comprise, in this superimposition order, at least:
a sub-cell A as described before, comprising in this superimposition order:
   a metallisation layer;
   a layer made of highly N⁺ (or P⁺) doped polycrystalline silicon “poly-Si(n+)”;
   a so-called passivation layer, for example made of silicon oxide, in particular of SiO₂;
   a substrate made of N-doped (or P-doped) crystalline silicon “c-Si(n)”;
   a so-called passivation layer, for example made of silicon oxide, in particular of SiO₂;
   a layer made of highly doped polycrystalline silicon of the electrical type opposite to that of the P⁺ (or N⁺) substrate “poly-Si(p+)”;
   a layer made of very highly doped polycrystalline silicon of the electrical type opposite to that of the underlying layer made of N⁺⁺ (or P⁺⁺) polycrystalline silicon “poly-Si(n++)”;
a sub-cell B as described before comprising in this superimposition order:
   a lower conductive or semiconductor layer of the N type (denoted “ETL”) in the case of a NIP structure or of the P type (denoted “HTL”) in the case of a PIN structure;
   a perovskite-type active layer;
   an upper conductive or semiconductor layer of the P type (denoted “HTL”) in the case of a NIP structure or of the N type (denoted “ETL”) in the case of a PIN structure;
said N-type layer being based on individualised nanoparticles of N-type metal oxide(s), and having an atomic carbon content lower than or equal to 20%;
   a second electrode, called the upper electrode E2^{B}, in particular metallised.

According to a particular embodiment, as illustrated in FIG. 6, a PK/TOPCon tandem photovoltaic device in a 2T structure according to the invention comprises the poly-Si (n+)/SiO₂/c-Si (n)/SiO₂/poly-Si (p+)/poly-Si (n++)/ETL/PK/HTL/E2^{B} stack, the metallisations not being represented.

It should be understood that the layers of this stack may have the characteristics described before for each of these layers.

Advantageously, as described in the rest of the text, in the case of this last variant of the TOPCon-type sub-cell A, the sub-cell A and the superimposed perovskite-based sub-cell B may thus be connected for the preparation of the tandem device with two terminals, without implementing a so-called the recombination layer.

The upper electrode E2B may be associated with a metal grid as described in the context of the HET/perovskite devices.

The invention also relates to a method for manufacturing a TOPCon/perovskite tandem photovoltaic device with two terminals, in particular as described before, comprising at least the following steps:
1/ making a silicon-based sub-cell A in a TOPCon-type architecture, in particular as described before, with a “TOPCon 1” or “TOPCon 2” structure, comprising:
   a metallisation layer;
   a layer made of highly N⁺ (or P⁺) doped polycrystalline silicon “poly-Si(n+)”;
   a layer, called passivation layer, made of silicon oxide, in particular of SiO₂;
   a substrate made of N-doped (or P-doped) crystalline silicon “c-Si(n)”; and
in the case of a TOPCon 1 structure:
   a layer made of highly doped crystalline silicon of the electrical type opposite to that of the P⁺ (or N⁺) substrate “c-Si(p+)”;
or, in the case of a TOPCon 2 structure:
   a layer, called passivation layer, made of silicon oxide, in particular of SiO₂;
   a layer made of highly doped polycrystalline silicon of the electrical type opposite to that of the P⁺ (or N⁺) substrate “poly-Si(p+)”;
   a layer made of very highly doped polycrystalline silicon of the electrical type opposite to that of the underlying layer made of N⁺⁺ (or P⁺⁺) polycrystalline silicon “poly-Si(n++)”;
2/ possibly, in particular in the case of a “TOPCon 2” structure, forming, on the layer made of highly P⁺ doped (or N⁺ doped) crystalline silicon, an electronically conductive or semiconductor intermediate layer, called the recombination layer, advantageously indium-free;
3/ making a perovskite-based sub-cell B according to the following steps:
forming on the upper layer of the sub-cell A, in particular on said layer made of very highly N⁺⁺ (or P⁺⁺) doped polycrystalline silicon in the case of a TOPCon 1 structure, or, if it exists, on the recombination layer, in particular in the case of a TOPCon 2 structure, an N-type “ETL” (or P-type “HTL”) conductive or semiconductor layer, called the lower layer;
forming, on the surface of said lower conductive or semiconductor layer, said perovskite-type active layer;
forming, on the surface of said perovskite-type active layer, a P-type “HTL” (or N-type “ETL”) upper conductive or semiconductor layer.
said N-type conductive or semiconductor layer being formed from a dispersion of N-type metal oxide nanoparticles in a solvent medium, at a temperature lower than or equal to 150° C., and in operating conditions adjusted so as to obtain an atomic carbon content in said N layer, lower than or equal to 20%;
forming, on said upper conductive or semiconductor layer, an electrode, called the upper electrode, E2^{B}, in particular metallised.

A person skilled in the art is able to adapt the order of the different steps for manufacturing a two-terminal tandem cell.

The sub-cell A with a TOPCon structure may be prepared according to the previously-described steps.

The metallisation layer (intended to form the FAR of the tandem device) may be formed of deposition by screen-printing of an aluminium paste, on the surface of the layer of highly N⁺ (or P⁺) doped polycrystalline silicon “poly-Si(n+)”, followed by rapid annealing at high temperature.

When present, the recombination layer, in particular made of ITO, may be formed of PVD deposition (cathode sputtering).

Advantageously, the recombination layer is subjected, at its face intended to support the N-type or P-type conductive or semiconductor layer of the upper sub-cell B, to a prior UV-Ozone treatment, in particular for a duration ranging from 1 to 60, in particular about 30 minutes.

The perovskite-based sub-cell B may be formed according to the previously-described steps.

The metallisation of the upper electrode E2B (intended to form the front face of the tandem device), may be carried out as previously described for the HET/perovskite tandem device.

Of course, the tandem photovoltaic devices according to the invention may further include electrical connection means, which allow connecting the electrodes to supply an electrical circuit with current.

The tandem photovoltaic device may further comprise an anti-reflection coating on the surface, for example made of MgF₂. For example, the anti-reflection coating may have a thickness comprised between 50 and 200 nm, in particular between 90 and 110 nm, for example about 100 nm.

The invention will now be described by means of the following examples, given of course as a non-limiting illustration of the invention.

### Example 1

Relationship Between the Residual Carbon Content in the N-Type Layer and the Efficiency of a Single-Junction Perovskite-Based Cell:

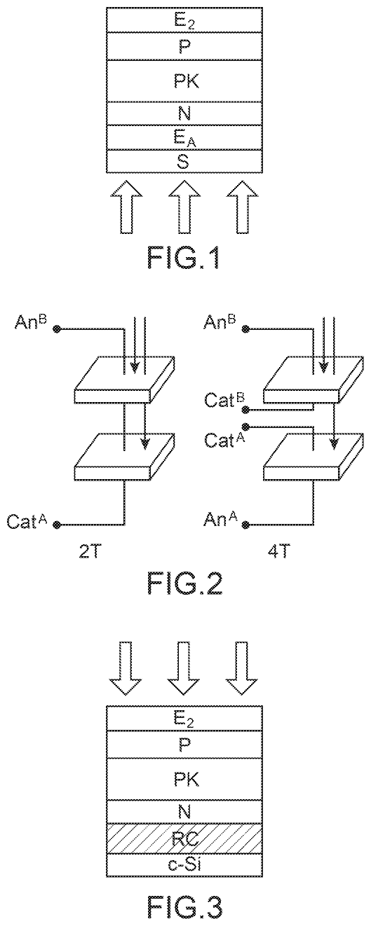

First, the efficiency of a N-type layer having a controlled carbon content is tested on a single-junction photovoltaic cell, in a “NIP” structure, as represented in FIG. 1.

The support (S) is a substrate made of glass with a thickness of 1.1 mm covered with an ITO conductive oxide layer forming the lower electrode (E₁).

Two types of perovskite materials are tested: the CH₃NH₃PbI₃ type (also denoted MAPbI₃) or the “double-cation” perovskite type CsₓFA₁₋ₓPb(I_{y}Br_{1-y})₃, FA symbolising the formamidinium cation.

The N-type layer (or ETL) is formed as described hereinbelow.
the P-type layer (or HTL) is composed of PTAA doped with a lithium salt, with an 80 nm thickness.
the upper electrode E₂ is a gold layer, with a 100 nm thickness.

Assessment of the Performances:

The active surface of the devices is 0.28 cm² and their performances have been measured at 25° C. under standard illumination conditions (1,000 W/m², AM 1.5G).

More particularly, the photovoltaic performances of the cells are measured by recording the current-voltage characteristics of the devices on a Keithley® SMU 2600 device under an AM 1.5G illumination at a power of 1,000 W·m⁻².

The tested cell is illuminated throughout the Glass/ITO face using an Oriel simulator.

A monocrystalline silicon cell calibrated in Fraunhofer ISE (Fribourg, Germany) is used as a reference to ensure that the luminous power delivered by the simulator is actually equal to 1,000 W·m⁻².

The characteristic parameters of the operation of the devices (open-circuit voltage Voc, short-circuit current density Jsc, form factor FF and conversion efficiency PCE) are determined from the current-voltage curves.

1.a. Formation of the N-Type Layer from an Ink Containing a Controlled Carbon Content:

Different N layers of tin oxide (SnO₂) are tested in a single-junction cell as described before.

The N layers, with a thickness of about 50 nm, are formed by spin-coating, carried out at room temperature, from distinct commercial solutions (called “inks”) of SnO₂ nanoparticles:
two dispersions of SnO₂ particles in water (Disp 1 and Disp 2), stabilised via the surface charge of the particles, and which differ from each other by the nature of the counter-ions; and
a dispersion (denoted Disp 3) of SnO₂ particles in a butanol mixture.

For these three dispersions, the size of the particles is in the range of 10-15 nm.

The dispersions 1 and 2 contain a reduced level of compatibilising agents, source of carbon, in comparison with the dispersion 3.

After application by spin-coating, the dispersions 1 and 2 lead to layers of SnO₂ nanoparticles containing about 15 atom % of carbon, whereas the dispersion 3 leads to a SnO₂ layer containing about 40 atom % of carbon.

The carbon content (atomic concentration) is determined by X-ray photoelectron spectroscopy (XPS standing for “X-Ray photoelectron spectroscopy”).

No post-deposition treatment of the N layers thus formed is carried out.

Results:

The carbon content for each of the formed N layers, as well as the performances of the different single-junction photovoltaic cells formed from these N layers, are reported in Table 1 hereinafter.

TABLE 1

| | | | PCE (%) |
|---|---|---|---|
| | Carbon content | PCE (%) | Double-cation |
| Ink | (% atom) | PK MAPbI₃ | PK |
| Disp. 1 | ~15 | 12.2 | 17.4 |
| Disp. 2 | ~15 | — | 18.0 |
| Disp. 3 | ~40 | 9.3 | 12.0 |

1.b. Formation of the N-Type Layer with Control of the Carbon Content by Carbon Elimination Post-Deposition Treatment:

Different N layers of aluminium-doped zinc oxide (AZO) and of tin oxide (SnO₂) are tested in a single-junction cell as described before, comprising a MAPbI₃-type perovskite layer.

The N layers, with a thickness of about 50 nm, are formed at room temperature, by spin-coating from distinct commercial solutions of AZO or SnO₂ nanoparticles, where appropriate followed by a carbon elimination treatment, by UV irradiation, by UV-ozone or with ozone, as detailed hereinbelow.

The dispersion 4 (Disp 4) is a dispersion of Al-doped ZnO or AZO, with an average size of 12 nm, in 2-propanol.

The treatment by UV irradiation of the N layer, after deposition of the dispersion by spin-coating, is carried out for 30 minutes, at a wavelength of 185 nm and 256 nm, under an inert atmosphere and at room temperature.

The treatment by UV-ozone is carried out by exposure to a UV radiation generating ozone of the surface of the N layer, after deposition of the dispersion by spin-coating, under room atmosphere and temperature, for 30 minutes in equipment from the brand JetLight.

The treatment with ozone is carried out in the same JetLight equipment and under the same conditions, except that the sample is placed behind a filter avoiding exposure to the UV radiation but suitable for exposure to the generated ozone for 30 minutes.

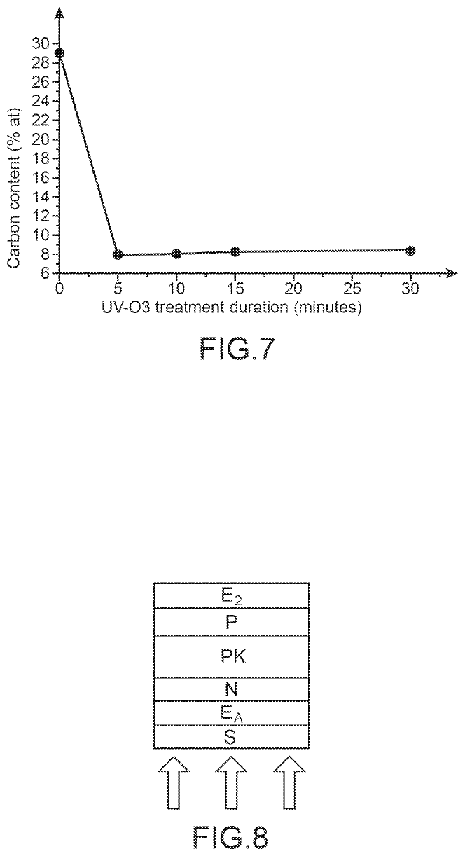

The different treatments (UV, UV-ozone, ozone irradiation) allow reducing the carbon content of the deposited layer. For example, FIG. 7 represents the evolution of the carbon content in a N layer based on AZO nanoparticles as a function of the duration of the UV-ozone treatment.

Results:

The carbon content for each of the N layers thus formed, after the carbon elimination treatment, as well as the performances of the different single-junction photovoltaic cells integrating each of these N-type conductive layers, are reported in Table 2 hereinafter.

TABLE 2

| | Treatment | Carbon content | PCE (%) |
|---|---|---|---|
| Ink | (duration) | (% atom) | PK MAPbI₃ |
| AZO Disp. 4 | — | 29 | <2.0 |
| AZO Disp. 4 | UV-O₃ | 8 | 11 |
| | (30 min) | | |
| SnO₂ Disp. 3 | — | 39 | 9.3 |
| SnO₂ Disp. 3 | UV-O₃ | 12.5 | 12.5 |
| | (30 min) | | |
| SnO₂ Disp. 3 | UV | 12.5 | 12.9 |
| | (30 min) | | |
| SnO₂ Disp. 3 | O₃ | 12.5 | 12.6 |
| | (30 min) | | |

### Example 2

Test of the implementation of a N-type layer with a controlled carbon content in a single-junction cell with illumination from the top.

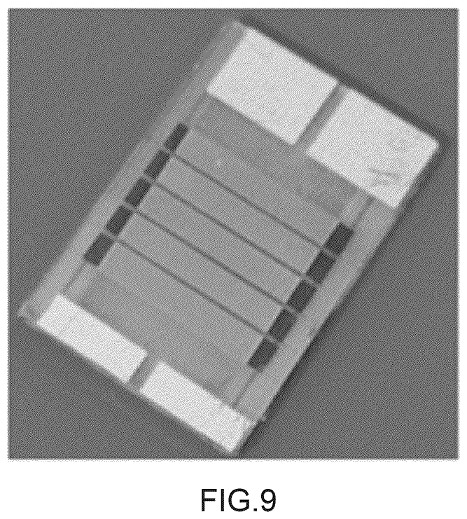

A single-junction cell is built according to an architecture, as represented in FIG. 8, with illumination from the top (transparent upper electrode), similar to that of the perovskite junction in a tandem device.

The support (S) is a substrate made of glass with a thickness of 1.1 mm covered with an ITO conductive oxide layer forming the lower electrode (E₁).

The perovskite material is Cs_{0.05}FA_{0.95}Pb(I_{0.83}Br_{0.17})₃, FA symbolising the formamidinium cation.

The N-type layer (or ETL), with a 40 nm thickness, is formed from the dispersion “Disp 2” as described in Example 1;
the P-type layer (or HTL) is composed of PTAA doped with a lithium salt, with an 80 nm thickness.
the upper electrode E₂ is an ITO (TCO) layer, formed by PVD (sputtering) with a 200 nm thickness.

The made PV device is composed of five strips (cells) connected in series (photograph in FIG. 8). The width of the strips is adjusted (which width?) in order to limit the resistive losses in the upper TCO layer whose conductivity is relatively limited.

The characteristic parameters of the operation of the device (open-circuit voltage Voc, short-circuit current density Jsc, form factor FF and power conversion efficiency PCE) are determined from the current-voltage curves.

The obtained results are reported in Table 3 hereafter.

TABLE 3

| Single-junction | Voc | Jsc | FF | PCE |
|---|---|---|---|---|
| device | (mV) | (mA/cm²) | (%) | (%) |
| With a N layer | 5,773 +/− 13 | 3.4 +/− 0.2 | 66.9 +/− 1.3 | 13.2 +/− 0.9 |
| formed from | | | | |
| the Disp. 2 | | | | |

### Example 3

Making of a HET/Perovskite Tandem Device Wherein the Perovskite-Based Sub-Cell Integrates a N Layer with a Controlled Carbon Content According to the Invention

Making of a HET/Perovskite Tandem Cell According to the Invention

A HET/perovskite tandem cell as represented in FIG. 4 and whose perovskite-based sub-cell integrates a N layer (ETL) with a controlled carbon content according to the invention may be prepared according to the following manufacturing process:

Cleaning by SDR (“saw damage removal”) and texturing (with KOH) of a silicon wafer;

Chemical-mechanical polishing (CMP) of one face of the wafer to facilitate the homogeneity of the liquid depositions of the upper sub-cell;

Post-CMP cleaning: successive soaking in ultrasound baths of water and IPA at 80° C. UV-Ozone treatment: 30 minutes. Treatment with an alkaline solution (SC1), with a powerful oxidising agent (SC2) then with the hydrofluoric acid (HF);

PEVCVD deposition of the non-doped (i) and (n) and (p) type (excess of electrons and holes respectively) doped amorphous silicon layers;

Thickness of the layers (i): between 5 and 15 nm; of the layer (n): between 1 and 10 nm; of the layer (p): between 5 and 15 nm.

PVD (cathode sputtering) deposition of two layers of indium-doped tin oxide (ITO):
70 nm over the textured rear face (FAR), therefore over the a-Si(n) layer in a NIP architecture;
12 nm over the other CMP polished face, therefore over the a-Si(p) layer in a NIP architecture, this layer being intended to form the recombination layer.

FAR metallisation by silver evaporation: 200 nm. This metallisation step is done only at the end of the manufacture of the devices in the case where it is carried out by screen-printing. The FAV and FAR metallisation are then deposited and annealed together.

UV-Ozone treatment on the face covered by the recombination ITO: 30 minutes;

In glove box:
Deposition of the SnO₂ layer by spin-coating from the dispersion “Disp 1” or the dispersion “Disp 2” described in Example 1, containing a reduced level of compatibilising agents, source of carbon.

Afterwards, the layer is annealed for 1 minute at 80° C. on a hot plate. The formed N layer (ETL) is 40 nm.
Deposition of the perovskite layer by spin-coating. An anti-solvent (chlorobenzene) is dispensed 5 seconds before the end of the rotation. Annealing 1 hour at 100° C. The formed perovskite-type layer is 250 nm.
Deposition of the PTAA layer by spin-coating. No annealing. The formed P layer (HTL) is 25 nm.

Au, 0.2 nm, evaporation. This layer is intended to improve transport at the composite layer/ITO interface;

PVD deposition of the ITO in FAV: 200 nm, without preheating to limit as much as possible the degradation of the heat-sensitive layers;

Evaporation of the Au contacts: 200 nm (unless the contacts are made by screen-printing).

The characteristic parameters of the operation of the tandem device (open-circuit voltage Voc, short-circuit current density Jsc, form factor FF and power conversion efficiency PCE) are determined from these current-voltage curves.

The obtained results are reported in Table 4 hereafter.

TABLE 4

| PK/HET | | | | |
|---|---|---|---|---|
| tandem | Voc | Jsc | FF | PCE |
| device | (mV) | (mA/cm²) | (%) | (%) |
| With an | 1,769 +/− 12 | 12.3 +/− 0.4 | 67.6 +/− 1.2 | 14.7 +/− 0.3 |
| ETL layer | | | | |
| formed from | | | | |
| the Disp. 1 | | | | |
| With an | 1,688 +/− 53 | 11.9 +/− + | 50.8 +/− 10.1 | 10.4 +/− 3.3 |
| ETL layer | | | | |
| formed from | | | | |
| the Disp. 2 | | | | |

### LIST OF THE MENTIONED DOCUMENTS

Xiao et al., Angew. Chem. 2014, 126, 1-7;
Allen et al., Nature Energy, 4(11), 914-928
Al-Ashouri et al., Energy Environ. Sci., 2019, 12, 3356-3369.

What is claimed is:

1.-15. (canceled)

16. A tandem photovoltaic device, comprising, in this superimposition order:
A/ a silicon-based sub-cell A comprising at least:
a substrate made of crystalline silicon; and
at least one layer, distinct from said substrate, made of N- or P-doped amorphous or polycrystalline silicon; and
B/ a perovskite-based sub-cell B, comprising at least:
an N-type conductive or semiconductor layer;
a P-type conductive or semiconductor layer; and
a perovskite-type layer that is active from a photovoltaic point of view, interposed between said N-type and P-type conductive or semiconductor layers,
wherein said N-type conductive or semiconductor layer is based on individualised nanoparticles of N-type metal oxide(s), and has an atomic carbon content lower than or equal to 20%,
the active layer being in contact with the N-type metal oxide individualised nanoparticles.

17. The tandem photovoltaic device according to claim 16, wherein said sub-cell A is a silicon heterojunction sub-cell or a TOPCon-type architecture sub-cell.

18. The tandem photovoltaic device according to claim 16, wherein said sub-cell A is a silicon heterojunction sub-cell, comprising, in this stacking order:
a first electrode denoted E1^{A};
a layer made of N-doped or P-doped amorphous silicon;
said substrate made of crystalline silicon;
a layer made of P-doped or N-doped amorphous silicon; and
optionally, a second electrode E2^{A}.

19. The tandem photovoltaic device according to claim 16, wherein said sub-cell A is a TOPCon-type architecture sub-cell, comprising:
said substrate made of N- or P-doped crystalline silicon;
at the face of the substrate intended to form the rear face of the tandem photovoltaic device, a layer made of highly N+ or P+ doped polycrystalline silicon, said layer made of highly doped polycrystalline silicon being separated from said substrate by a passivation layer made of oxide so-called “tunnel oxide”;
on the side of the opposite face of the substrate, at least one layer made of highly P+ or N+ doped crystalline or polycrystalline silicon of the electrical type opposite to that of the substrate.

20. The tandem photovoltaic device according to claim 16, wherein said N-type metal oxide nanoparticles are selected from among particles of zinc oxide, titanium oxides TiOₓ with x comprised between 1 and 2, tin oxide, doped zinc oxides, doped titanium oxides; and mixtures thereof.

21. The tandem photovoltaic device according to claim 16, wherein said metal oxide nanoparticles have an average particle size comprised between 2 and 100 nm.

22. The tandem photovoltaic device according to claim 16, wherein said N-type conductive or semiconductor layer of the sub-cell B has an atomic carbon content lower than or equal to 17%.

23. The tandem photovoltaic device according to claim 16, wherein said perovskite-type active layer of the sub-cell B is formed by a perovskite material of formula ABX₃, with:
A representing a cation or a combination of metallic or organic cations; B representing one or more metallic element(s), chosen among lead, tin, bismuth and antimony; and
X representing one or more halide(s) anion(s);
said perovskite material of formula CsₓFA₁₋ₓPb(I_{1-y}Br_{y})₃ with x<0.17; 0<y<1 and FA symbolising the formamidinium cation.

24. The tandem photovoltaic device according to claim 16, wherein said perovskite-based sub-cell B comprises, in this stacking order:
optionally a first electrode E1^{B};
said lower conductive or semiconductor layer of the N type in the case of a NIP structure or of the P type in the case of a PIN structure;
said perovskite-type active layer;
said upper conductive or semiconductor layer of the P type in the case of a NIP structure or of the N type in the case of a PIN structure,
said N-type layer being based on individualised nanoparticles of N-type metal oxide(s), and has an atomic carbon content lower than or equal to 20%,
a transparent second electrode, called the upper electrode, E2^{B}, and more particularly formed of a layer made of metallised transparent conductive oxide.

25. The tandem photovoltaic device according to claim 18, said device being of the HET/perovskite type with a 2T structure, comprising, in this superimposition order, at least:
a sub-cell A, wherein sub-cell A is a silicon heterojunction sub-cell comprising, in this superimposition order:
a first electrode denoted E1^{A};
a layer made of N-doped or P-doped amorphous silicon;
a substrate made of crystalline silicon;
a layer made of P-doped or N-doped amorphous silicon;
an electronically conductive or semiconductor intermediate layer, called “recombination layer”;
a perovskite-based sub-cell B, comprising in this superimposition order:
said lower conductive or semiconductor layer of the N type in the case of a NIP structure or of the P type in the case of a PIN structure;
said perovskite-type active layer;
said upper conductive or semiconductor layer of the P type in the case of a NIP structure or of the N type in the case of a PIN structure, and
said second electrode, called the upper electrode, E2^{B}.

26. The device according to claim 16, wherein the N-type metal oxide individualised nanoparticles are made of SnO₂.

27. A method of manufacturing a tandem photovoltaic device according to claim 16, comprising at least the following steps:
(a) making said silicon-based sub-cell A; and
(b) making said sub-cell B via at least one step of forming said N-type conductive or semiconductor layer from a dispersion of N-type metal oxide nanoparticles in a solvent medium, at a temperature lower than or equal to 150° C., and in operating conditions adjusted so as to obtain the desired atomic carbon content in said N layer, lower than or equal to 20%;
and a step during which the active layer is formed over the surface of the N-type metal oxide nanoparticles.

28. The method according to claim 27, wherein said N-type conductive or semiconductor layer is formed at a temperature lower than or equal to 120° C.

29. The method according to claim 27, wherein the carbon content in said N-type conductive or semiconductor layer is controlled by adjusting the level of carbon precursor compounds of the implemented dispersion of metal oxide nanoparticles.

30. The method according to claim 27, wherein the carbon content in said N-type conductive or semiconductor layer is controlled, by subjecting, after deposition of said dispersion of metal oxide nanoparticles and prior to the deposition of the overlying layer, the N-type layer to a treatment for eliminating carbon.

31. The method according to claim 30, wherein the treatment for eliminating carbon is a treatment by UV irradiation, by UV-ozone, with ozone or by plasma.
